(19) United States
(12) Patent Application Publication
(10) Pub. No.: US 2023/0160980 A1
(43) Pub. Date: May 25, 2023

(54) METHODS AND SYSTEMS FOR OBTAINING FLEXIBLE FREQUENCY SELECTION AND HIGH EFFICIENCY ON A LOW FREQUENCY MAGNETIC FIELD POSITION DETERMINATION

(71) Applicant: JØRGEN SELMER JENSEN, HJERM (DK)

(72) Inventor: JØRGEN SELMER JENSEN, HJERM (DK)

(21) Appl. No.: 17/157,961

(22) Filed: Jan. 25, 2021

Related U.S. Application Data
(60) Provisional application No. 62/965,333, filed on Jan. 24, 2020.

(51) Int. Cl. G01R 33/025; G06F 3/01

(52) U.S. Cl. CPC G01R 33/025; G06F 3/011

(57) ABSTRACT

A system for obtaining flexible frequency selection and high efficiency on a low frequency magnetic field position determination.

### CLAIM OF PRIORITY

The present applications claims priority to and incorporates by reference in its entirety U.S. Provisional Pat. Application No. 62965333, filed on Jan. 24, 2020, and titled METHODS AND SYSTEMS FOR OBTAINING FLEXIBLE FREQUENCY SELECTION AND HIGH EFFICIENCY ON A LOW FREQUENCY MAGNETIC FIELD POSITION DETERMINATION.

### BACKGROUND

With the proliferation of games, virtual reality, sports training and the like, there is a greater use for the ability to determine the position and follow human movements. In this case, it can be preferable to be free from attached wires. One option for wire-free systems can be based on battery technology and therefore can be minimal power demanding. These types of systems should operate near each other and be robust to noisy sources. Current techniques for using low frequency magnetic fields have several issues. For example, one option is to use the resonant principle in the transmitter system. However, this can have one disadvantage in that it is not well suited to make a free choice of transmit/receive frequency. The transmission frequency is locked by the chosen and mounted components. Accordingly, improvements to system with wired attachment systems that are used to determine the position and movement of human is desired.

### SUMMARY OF THE INVENTION

A system for obtaining flexible frequency selection and high efficiency on a low frequency magnetic field position determination.

### BRIEF DESCRIPTION OF THE DRAWINGS

FIG. 1 illustrates an example branch of a human position/motion system, according to some embodiments.

FIG. 2 illustrates an example system for obtaining flexible frequency selection and high efficiency on a low frequency magnetic field position determination, according to some embodiments.

The Figures described above are a representative set and are not an exhaustive with respect to embodying the invention.

### DESCRIPTION

Disclosed are a system, method, and article of manufacture for obtaining flexible frequency selection and high efficiency on a low frequency magnetic field position determination. The following description is presented to enable a person of ordinary skill in the art to make and use the various embodiments. Descriptions of specific devices, techniques, and applications are provided only as examples. Various modifications to the examples described herein can be readily apparent to those of ordinary skill in the art, and the general principles defined herein may be applied to other examples and applications without departing from the spirit and scope of the various embodiments.

Reference throughout this specification to “one embodiment,” “an embodiment,” ‘one example,’ or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, and they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

### Definitions

Example definitions for some embodiments are now provided.

Class-D amplifier/switching amplifier is an electronic amplifier in which the amplifying devices (transistors, e.g. MOSFETs) operate as electronic switches, and not as linear gain devices as in other amplifiers.

Low-frequency magnetic fields can include frequencies that are meant to be so low that the predominant physics of the distribution of the fields follows H = C/S3. Where H is the field strength [A/m], C is a constant and S is the distance between the transmitter and the receiver.

Metal-oxide-semiconductor field-effect transistor (MOSFET/ MOS transistor) is a type of insulated-gate field-effect transistor (IGFET) that is fabricated by the controlled oxidation of a semiconductor (e.g. in silicon).

Q factor can be a measurement of a resonant system’s relative bandwidth.

Resonance system can be a coupling where the energy moves back and forth between the coil and the capacitor. The more lossless the coil and capacitor, the less energy is lost during this process.

### Example Systems and Methods

The present invention combines a transmitter coil with a switched amplifier to determine the position and follow human movements. In this way, a full efficiency can be achieved. A human position/motion system is then free to choose a suitable transmission frequency without changing components.

It is noted It is possible to implement a spatial position determination using low frequency magnetic fields. To determine the position, magnetic fields are required in three (3) mutually perpendicular directions (called X, Y, Z). Likewise, a receiver consisting of three (3) mutually perpendicular magnetic field receivers is required. Each of the three receivers records the value of the signal they receive from the X, Y, Z magnetic fields. Based on the received signals, the receiver can calculate the position in relation to the transmitter that emits the three fields. The system and methods herein can be used to solve the problems with a resonance system of the human position/motion system without cost in efficiency.

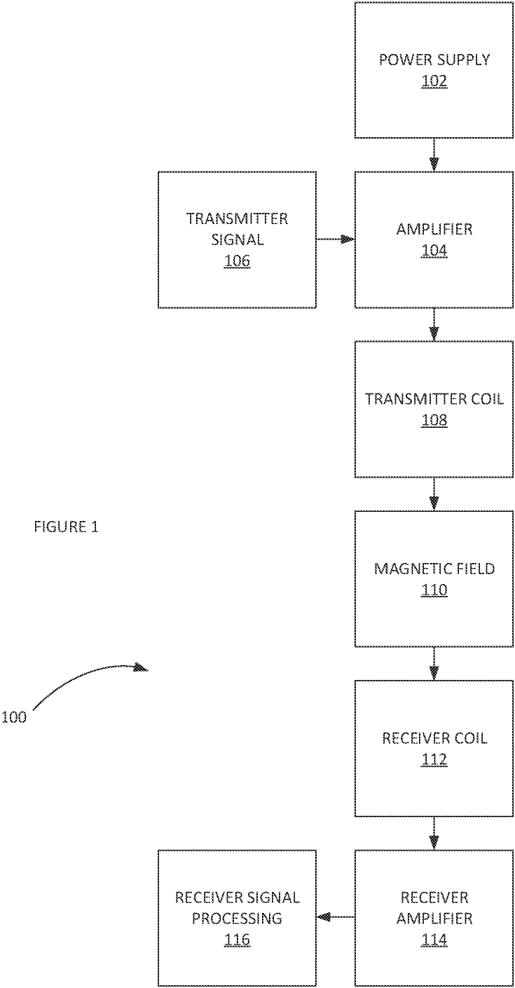

FIG. 1 illustrates an example branch of a human position/motion system 100, according to some embodiments. It is noted that FIG. 1 shows a schematic organization of one branch of three branches utilized for spatial determination. Power supply 102 supplies the power demanding part that creates the magnetic field in the room. Transmitter signal 106 comprises a device that creates the signal to be transmitted. Amplifier 104 is an amplifier which combines the output of power supply 102 and transmitter signal 106 106. In this way, amplifier 104 generates the voltage and current which influence transmitter coil 108.

When an electric current passes through the transmitter coil 108, a magnetic field 110 is formed. At a distance from, and at an angle to, transmitter coil 108, a portion of this field passes through the receiver coil 112. The collected signal is amplified by receiver amplifier 114. Receiver amplifier 114 converts the collected signal to a digital signal. Subsequently, receiver signal processing 116 is performed. Receiver signal processing 116 can include various subsystems (e.g. bandpass filters, detectors and Kalman filtering etc.), for determining the position.

Transmitter signal 106 can be a sinewave amplified by amplifier 104. Amplifier 104 can be built around the transmitter coil 108. In some embodiments, transmitter coil 108 can be a coil wound by copper. In some embodiments, ferrite is can be used in transmitter coil 108. Transmitter coil 108 can have a high Q factor. In this way, the reactive part of transmitter coil 108 is thus dominant in relation to the loss-making part. This can be used to form a dt circuit around the transmitter coil.

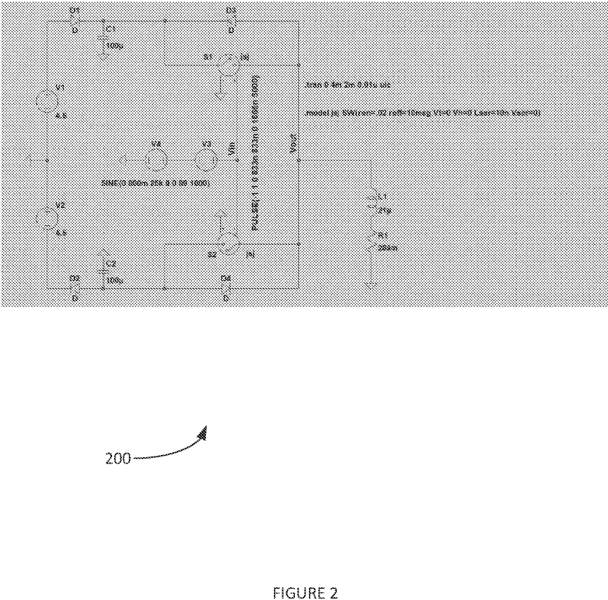

FIG. 2 illustrates an example system 200 for obtaining flexible frequency selection and high efficiency on a low frequency magnetic field position determination, according to some embodiments. The transmitter coil to make the magnetic field is shown as L1 in series with R1. The signal to the transmitter coil, is supplied from a class D amplifier (e.g. a switched amplifier).

The operation of the class D amplifier is as follows. V4 is the signal to be represented as the voltage across the transmitter coil. In the present example, this is shown as a sinus generator with a frequency of 25 KHz.

The modulation frequency is V3. V3 is a sawtooth generator which is added to V4. S1 and S2 are controlled switches. S1 and S2 are set in an on state when the control voltage is above 0V and off when it is below 0V. S1 and S2 can be made of based on N-channel MOS transistors.

D3 and D4 can be built into the MOS transistors and always serve to ensure a current path for the coil L1. For purposes of illustration and not of limitation, the present example the principle is introduced using: 2 diodes, D1 and D2, and 2 capacitors, C1 and C2. As with the class B amplifier, current and voltage across the transmitter coil are phase-shifted ninety (90) degrees. However, instead of dissipating the power in the series elements Q1 and Q2, the excess current is fed back to C1 and C2 respectively. As in a resonant coupling, the energy moves back and forth between the self-induction of the transmitter coil and, in the present example, C1 and C2. The size of C1 and C2 can be irrelevant if they are sufficient in size. In this way, the frequency and amplitude of the transmitter signal can be selected. As the efficiency is high, a high Q self-induction can be fed.

### Conclusion

Although the present embodiments have been described with reference to specific example embodiments, various modifications and changes can be made to these embodiments without departing from the broader spirit and scope of the various embodiments. For example, the various devices, modules, etc. described herein can be enabled and operated using hardware circuitry, firmware, software or any combination of hardware, firmware, and software (e.g., embodied in a machine-readable medium).

In addition, it can be appreciated that the various operations, processes, and methods disclosed herein can be embodied in a machine-readable medium and/or a machine accessible medium compatible with a data processing system (e.g., a computer system), and can be performed in any order (e.g., including using means for achieving the various operations). Accordingly, the specification and drawings are to be regarded in an illustrative rather than a restrictive sense. In some embodiments, the machine-readable medium can be a non-transitory form of machine-readable medium.

1. (canceled)

2. A system for obtaining flexible frequency selection and high efficiency on a low frequency magnetic field position determination
a transmitter coil combined with a switched amplifier configured to determine the position and follow one or more human movements; and
a human position/motion system comprising a receiver, wherein the human position/motion system configured to select a suitable transmission frequency without changing components.

3. The system of claim 2, wherein human position/motion system implements a spatial position determination using low frequency magnetic fields.

4. The system of claim 3, wherein the human position/motion system determines the position using a plurality of magnetic fields.

5. The system of claim 4, wherein the plurality of magnetic fields are in three (3) mutually perpendicular directions (called X, Y, Z).

6. The system of claim 5 further comprising:
a receiver comprising of three (3) mutually perpendicular magnetic field receivers.

7. The system of claim 6, wherein each three (3) mutually perpendicular magnetic field receivers records a value of the signal they receive from the X, Y, Z magnetic fields.

8. The system of claim 7, wherein, based on the received signals, the receiver calculates the position in relation to the transmitter that emits the three fields.

9. The system of claim 8, wherein the receiver is used to solve the problems with a resonance system of the human position/motion system.

10. The system of claim 9, wherein the receiver is used to solve the problems with a resonance system of the human position/motion system. without cost in efficiency.

11. A three-branched human position/motion system comprising:
wherein each branch of three three-branched human position/motion system is utilized for a spatial determination,
wherein each branch of three three-branched human position/motion system comprises:
a power supply to supply a power demanding part that creates a magnetic field in a room;
a transmitter signal comprising a device that creates a transmitted signal to be transmitted;
an amplifier configured to combine an output of a power supply and a transmitter signal;
a transmitter coil;
a receiver coil;
a receiver amplifier;
an amplifier configured to generate a voltage and a current which influence the transmitter coil an electric current passes through the transmitter coil, a magnetic field is formed at a distance from, and at an angle to, the transmitter coil 108, a portion of the magnetic field passes through the receiver coil, where a collected signal is amplified by the receiver amplifier, wherein the receiver amplifier converts the collected signal to a digital signal.

12. The three-branched human position/motion system of claim 11, wherein a receiver signal processing is performed.

13. The three-branched human position/motion system of claim 12, wherein the receiver signal processing comprises a bandpass filter.

14. The three-branched human position/motion system of claim 12, wherein the receiver signal processing comprises a detector.

15. The three-branched human position/motion system of claim 12, wherein the receiver signal processing comprises a Kalman filter.

16. The three-branched human position/motion system of claim 12, wherein the receiver signal processing determines a position.

17. The three-branched human position/motion system of claim 12, wherein the transmitter signal comprises a sinewave amplified by the amplifier.

18. The three-branched human position/motion system of claim 17, wherein the amplifier is built around the transmitter coil.

19. The three-branched human position/motion system of claim 17,
wherein the transmitter coil comprises a coil wound by copper,
wherein the transmitter coil comprises a ferrite material with a high Q factor such that a reactive part of the transmitter coil is dominant in relation to a loss-making part of the transmitter coil.
